(19) United States
(12) Patent Application Publication
(10) Pub. No.: US 2024/0361437 A1
(43) Pub. Date: Oct. 31, 2024

(54) METHODS AND APPARATUS FOR SINGLE-SHOT TIME-OF-FLIGHT RANGING WITH BACKGROUND LIGHT REJECTION

(71) Applicants: HUAWEI TECHNOLOGIES CO., LTD., SHENZHEN (CN); POLITECNICO DI MILANO, Milano (IT)

(72) Inventors: Alfonso INCORONATO, Tavazzano con Villavesco (IT); Klaus PASQUINELLI, Seriate (IT); Mauro LOCATELLI, Nembro (IT); Franco ZAPPA, Milano (IT); Ali Ahmed Ali MASSOUD, Kanata (CA); Haitao SUN, Kanata (CA); Hongbiao GAO, Shenzhen (CN); Li ZENG, Shenzhen (CN)

(73) Assignees: HUAWEI TECHNOLOGIES CO., LTD., SHENZHEN (CN); POLITECNICO DI MILANO, Milano (IT)

(21) Appl. No.: 18/768,697

(22) Filed: Jul. 10, 2024

Related U.S. Application Data
(63) Continuation of application No. PCT/CN2022/075580, filed on Feb. 9, 2022.

(51) Int. Cl. G01S 7/487; G01S 7/4863; G01S 7/4865; G01S 17/10

(52) U.S. Cl. CPC G01S 7/487; G01S 7/4863; G01S 7/4865; G01S 17/10

(57) ABSTRACT

There is provided a method and device for time-of-flight (TOF) ranging. The method includes generating, by each photon detector in a photon detector array, a quantized current pulse each time a predefined number of photons is detected. The method further includes summing, by a current adder, the quantized current pulses from all photon detectors to create an analog signal pulse. The method further includes providing, by a peak detector, a digital pulse for each instance where an intensity of the analog signal pulse is greater than signal peaks already measured after the last emitted pulsed laser shot. The method further includes measuring and recording, by a time-to-digital converter (TDC), a TOF each time the digital pulse is provided. The method further includes providing, by a TOF output, a single TDC result indicative of a TOF associated with the analog signal pulse having a highest intensity. The device includes a photon detector, current adder, analog peak detector and a time-of-flight digital converter, wherein each component is configured to perform the respective aspect of the method.

### CROSS-REFERENCE TO RELATED APPLICATIONS

The present application is a continuation of International Application No. PCT/CN2022/075580 filed Feb. 9, 2022 and entitled “METHODS AND APPARATUS FOR SINGLE-SHOT TIME-OF-FLIGHT RANGING WITH BACKGROUND LIGHT REJECTION”, the contents of which are incorporated herein in their entirety.

### FIELD

The present disclosure pertains to the field of optical sensors for light detection and ranging, and in particular to a single-shot time-of-flight ranging sensor.

### BACKGROUND

Detecting a very weak optical signal in a strong background illumination is an extremely difficult task. A critical application is light detection and ranging (LIDAR), where an object's distance is measured through the round-trip time-of-flight (TOF) of light pulses. The light pulses travel from a device including an emitter and a sensor, wherein the light travels from the emitter to the object in the scene and back to the sensor. Applications such as in automotive environments in daylight conditions can have a strong background illumination which can hide the desired optical signal.

Standard TOF LIDAR techniques are primarily based on repetitive laser shots and the collection of TOF measurements (usually one per laser shot), similar to the time-correlated single-photon counting (TCSPC) technique. Each TOF measurement is stored in a form of a histogram and eventually the baseline due to background light is measured and removed while the centroid of the TOF peak is computed. The number of laser shots (i.e., measurement repetitions) must be sufficiently high in order to acquire a sufficiently detailed histogram, in order to identify and discard the unwelcomed TOFs resulting from background photons, while identifying the useful TOFs due to the laser pulse's photons. Subsequently computation of the final TOF value from the centroid of the histogram peak distribution can be performed. In this way, by knowing the speed of light, c, in the medium (for example, in air c=300,000 km/s), the object's distance may be computed through d=½·c·TOF, with a sufficient confidence and signal-to-noise ratio.

LIDAR techniques require fast and efficient detectors, able to detect extremely faint laser echoes overwhelmed by very high background rate. Single-photon detectors, such as avalanche photodiodes (APD), single-photon avalanche diodes (SPAD) and silicon photomultipliers (SiPM) may provide a desired level of quantum sensitivity, (i.e., they are able to detect a single photon of light). However these devices must be properly employed to be able to discriminate the useful signal photons while avoiding saturation caused by unwelcome background photons. Moreover, the electronics usually drive repetitive laser shots, acquiring many TOF measurements and storing them into memory banks, in order to collect a histogram of many TOF measurements. Usually, background photons show random TOF measurements, scattered across the full-scale range of the measurement; instead, useful TOF measurements (returning from the object under observation) are concentrated in time, because the laser excitation is a pulse with sufficiently narrow width, for example usually few nanoseconds or tens of picosecond wide.

For a single-shot TOF ranging sensor, two main techniques may be implemented in order to identify the signal return after each laser shot. These techniques include the detection when a signal reaches a peak or detection when a signal crosses a threshold.

The peak acquisition technique usually requires a very fast analog-to-digital converter (ADC) to acquire the full signal waveform with sub-nanosecond conversion rates and subsequently a data post-processing to identify the useful laser peak and compute the actual TOF (e.g., the peak centroid, i.e., the geometric center of the histogram). The overall sensor of this configuration is expensive and bulky and communication between the sensor, ADC and data processor requires a high data-rate and time overhead.

The threshold technique (as illustrated in FIG. 1) usually requires a comparator to trigger a time-to-digital converter (TDC) when the signal crosses a threshold 101. The threshold is set higher than the unwelcomed background noise (for example defined as an almost flat baseline) and any stray light bursts (e.g., the first peak), in order to detect the useful laser pulse return (e.g., the second peak). The threshold technique solution is much simpler than the peak acquisition technique and promptly provides the TOF with a picosecond (e.g. millimeter) resolution. In order to reject background photons while detecting the laser echo (e.g. the desired returning laser pulse), the threshold must be adjusted to be higher than the background level of noise, but low enough to reduce the required laser pulse energy and to reach longer distances (i.e., to account for fainter light return). Unfortunately, such a threshold depends on sun intensity, time of day, object reflectivity, distance, and the like. As such the threshold must be continuously adjusted.

Other techniques employ a constant-fraction discriminator to find the signal peak, which improves accuracy, but still suffers from the aforementioned issues and high false alarm rates. As both laser returns and background light trigger many TOFs, it can be difficult to properly discriminate desired signals from undesired signals. Moreover, a constant-fraction discriminator must be designed to match the width of the optical pulse; therefore this solution is not suitable for reconfigurable electronics and for different LIDAR systems with various laser widths, detection electronics, or the like.

Accordingly, there is a need for new methods for the implementation of a single-shot TOF ranging sensor, that are not subject to one or more limitations of the prior art.

This background information is provided to reveal information believed by the applicant to be of possible relevance to the present invention. No admission is necessarily intended, nor should be construed, that any of the preceding information constitutes prior art against the present invention.

### SUMMARY

An object of embodiments of the present disclosure is to provide methods and devices for time-of-flight (TOF) ranging.

An aspect of the disclosure provides for a method fortime-of-flight (TOF) ranging. The method includes generating, by each photon detector in a photon detector array, a quantized current pulse each time a predefined number of photons is detected. The method further includes summing, by a current adder, the quantized current pulses from all photon detectors to create an analog signal pulse. The method further includes providing, by a peak detector, a digital pulse for each instance where an intensity of the analog signal pulse is greater than signal peaks already measured so far. The method further includes measuring and recording, by a time-to-digital converter (TDC), a TOF each time the digital pulse is provided. The method further includes providing, by a TOF output, a single TDC result indicative of a TOF associated with the analog signal pulse having the highest intensity.

In some embodiments the peak detector includes at least one of a peak stretcher and an increment detector. In some embodiments the increment detector includes at least one of an AC-coupling and a comparator. In some embodiments the predefined number of photons is one. In some embodiments the photon detector array includes at least one of a single-photon avalanche diode (SPAD), a silicon photomultiplier (SiPM), and an avalanche photodiode (APD). In some embodiments the method further includes sensing, by an amplitude sensor, an amplitude of the analog signal at one of a trans-impedance amplifier (TIA) and the analog peak detector. In some embodiments the amplitude of the analog signal pulse is proportional to a number of photons detected within a duration of time. In some embodiments the amplitude sensor comprises at least one of an analog-to-digital convertor (ADC) and a comparator. In some embodiments repeating the method provides a further TOF ranging. In some embodiments the peak detector is configured as a digital peak detector.

An advantage of the embodiments disclosed herein is that they may provide useful distance information at every laser shot. Compared to threshold-based sensors, the disclosed embodiments need neither background sensing, nor threshold adjustment, and provide one single TOF in a simpler way. Further, the embodiments are immune to false detections (due to noise peaks higher than the background baseline, but lower than the signal peak). Compared to ADC-based sensors, the disclosed embodiments are cost-effective, easier to design, require smaller area and lower power consumption and need neither ADC nor high-bandwidth readout.

Another advantageous aspect of the embodiments disclosed herein is that the same sensor may be employed together with multi-shots of the pulsed laser, so to accumulate a histogram of the individual TOFs for a single-spot of the object and to average all TOFs in order to improve distance precision. Moreover, the same sensor may be employed for acquiring multi-spots of the object, either with single- or multi-shots of the pulsed laser, by scanning the laser beam across the object, so to reconstruct the 3D map (x and y coordinates plus TOF distance) of the scene for wider field-of-view.

A further advantage of the embodiments disclosed herein is that embodiments of the present disclosure may be implemented as a single-chip, with no need of high-speed readout (resulting from just one TOF readout per single-shot laser pulse), nor external amplifiers, ADCs, processors, etc. Moreover, the present disclosure is very simple to use, as it just requires a synchronous pulse at every laser shot to activate the peak detector, reset the TDC, readout the previous TOF measurement, with no need of further external processing.

Another aspect of the disclosure provides for a device for time-of-flight ranging. The device includes a photon detector array including a plurality of photon detectors, each photon detector configured to generate a quantized current pulse each time a predefined number of photons is detected. The device further includes a current adder configured to sum the quantized current pulses from all photon detectors to create an analog signal pulse and a peak detector configured to output a digital pulse for each instance where an intensity of the analog signal pulse is greater than signal peaks already measured so far (i.e., since the last laser pulse shot). The device further includes a time-to-digital converter (TDC) configured to measure and record a time-of-flight (TOF) each time the digital pulse is provided and a TOF output configured to output a single TDC result indicative of a TOF associated with the analog signal pulse having the highest intensity.

Embodiments have been described above in conjunctions with aspects of the present disclosure upon which they can be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

### BRIEF DESCRIPTION OF THE FIGURES

Further features and advantages of the present disclosure will become apparent from the following detailed description, taken in combination with the appended drawings, in which:

FIG. 1 depicts a crossing of a threshold by a signal, according to the prior art.

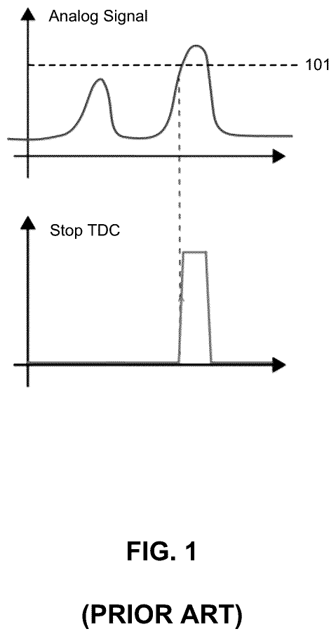

FIG. 2 illustrates a time-of-flight (TOF) ranging measurement, according to embodiments of the present disclosure.

FIG. 3 illustrates a method for time-of-flight (TOF) ranging, according to embodiments of the present disclosure.

FIG. 4 illustrates an analog architecture, according to embodiments of the present disclosure.

FIG. 5 illustrates a digital architecture, according to embodiments of the present disclosure.

FIG. 6 illustrates a single-photon avalanche diode (SPAD), according to embodiments of the present disclosure.

FIG. 7 illustrates an operation of a peak detector, according to embodiments of the present disclosure.

It will be noted that throughout the appended drawings, like features are identified by like reference numerals.

### DETAILED DESCRIPTION

Embodiments of the present disclosure describe a single-shot time-of-flight 3D ranging sensor based on a photon detector array (for example, a single-photon avalanche diode (SPAD) array, which in some instances may be considered to be a photon detector pixel array), triggered by an external laser pulse driver, generating an analog signal pulse proportional to the number of incoming photons. A peak detector tracks such an analog signal pulse and captures the highest intensity detected so far. Increment detection electronics provide a pulse each time a new peak (with an intensity higher than that previously detected) is detected, and a time measuring block (e.g., a time-to-digital converter (TDC)) is triggered by such a pulse in order to measure the associated TOF and to overwrite the previously saved value. After one single-shot of the laser, the sensor provides one TOF measurement, corresponding to the TOF of the highest detected peak, which belongs to the pulsed laser echo due to the photons associated therewith being concurrent in time, while background photons are randomly scattered in time. Therefore, the sensor outputs one single TOF measurement corresponding (through the speed of light, c) to the distance of the object spotted in the scene under observation. This method results in no need for repetitive measurements (i.e., laser shots), nor storing of the full analog waveform of the detected light intensity, nor conversion of such a waveform into a digital data stream (e.g., by means of an analog-to-digital converter (ADC)), nor selecting a threshold to identify when the return signal exceeds the background level, nor reading out and storing multiple TOFs, nor identifying peaks in post-processing. It will be understood that while single-photon avalanche diodes (SPADs) may be referred to extensively throughout the present disclosure as an example, other photon detectors or single-photon detectors may be used instead of SPADs. Examples of such other photon detectors and single photon detectors are further discussed elsewhere herein.

The sensor embeds both SPADs and on-chip electronics to identify the peak with the highest number of concurrent photons and to measure the associated TOF. The sensor is composed by a multitude of independent SPADs, each one generating a well-defined (in amplitude and width) current pulse each time a photon is detected. The quantized pulses are summed together into an overall analog signal pulse, having an intensity that is proportional to the number of incoming concurrent detected photons.

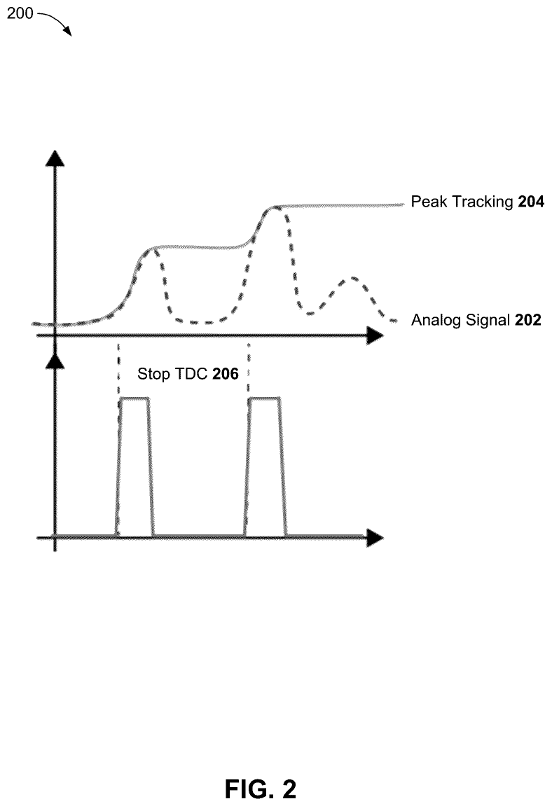

FIG. 2 depicts a time-of-flight (TOF) ranging measurement 200 according to embodiments of the present disclosure. The measurement 200 is based on embodiments of the present disclosure, which triggers the time measuring unit (e.g., an on-chip TDC) each time a new peak is detected (e.g. a peak higher than the highest peak previously detected). At the end of the defined range of interest, the TOF value stored in the single memory cell (e.g. each TOF overwrites the one previously saved) is the TOF of the highest return peak (e.g., the TOF of the single shot laser pulse).

Once the laser emits the single shot of light, the on-chip electronics tracks (illustrated as peak tracking 204) each peak of the detected analog signal 202 and provides a digital pulse at each peak increment. Thus, the last digital pulse signals the highest peak detected so far. A multi-hit TDC 206 latches the TOF of each digital pulse into a single memory cell, overwriting the previous content. At the end of the full-scale range (FSR) of interest (e.g., defined range of interest) and before the next laser pulse, the memory cell contains the TOF measurement for the highest detected peak of the laser return. The background photons (e.g., which may be considered to be optical noise) arrive randomly in time and thus do not build up into a peak. Instead, the photons associated with the light pulse are concentrated in time within the pulse width, thus standing out from the background baseline noise. In addition, possible stray light paths, giving rise to coincident photons, typically will provide an intensity lower than the back-and-forth direct path of the emitted light pulse.

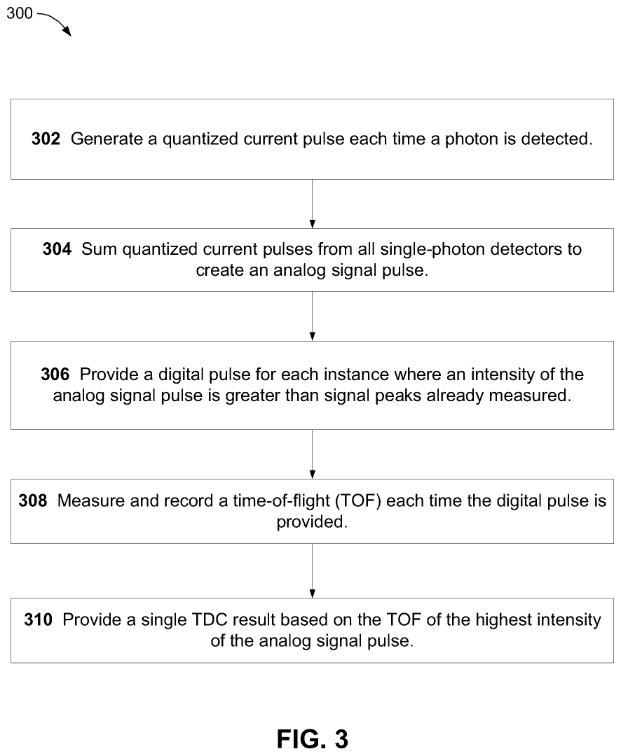

FIG. 3 is a flowchart of a method 300 for time-of-flight (TOF) ranging according to embodiments of the instant disclosure. The method 300 involves, at step 302, generating, by each photon detector pixel in a photon detector array, a quantized current pulse each time a photon is detected. The method 300 further involves, at step 304, summing, by a current adder, the quantized current pulses from each of the photon detector pixels to create an analog signal pulse. The method 300 further involves, at step 306, providing, by an analog peak detector, a digital pulse for each instance where an intensity of the analog signal pulse is greater than the highest signal peak previously measured. The method 300 further involves, at step 308, measuring and recording, by a time-to-digital converter (TDC), a TOF each time the digital pulse is provided. The method 300 further involves, at step 310, providing, by a TOF output, a single TDC result based on the TOF of the highest intensity of the analog signal pulse.

Instead of a sensor requiring multi-shot measurement repetitions, a single-shot time-of-flight 3D ranging sensor is capable of measuring the distance of one spot of a far-away object in just one acquisition. By shining one single shot of a pulsed light source (e.g. a laser pulse) and providing as an output one single TOF measurement of the highest return peak (e.g., with the highest number of time-coincident photons due to the laser pulse return and not random background photons), ambient background light may be rejected without a need for repetitive measurements. Having regard to the method according to embodiments, there may be no need to collect many TOF measurements, no need for memory storage associated with histogram collection, no post-processing for computation of a histogram baseline, no need to select an intensity threshold for identifying the laser signal return for defining a baseline for background noise, and no post-processing to compute the TOF centroid of the histogram's peak.

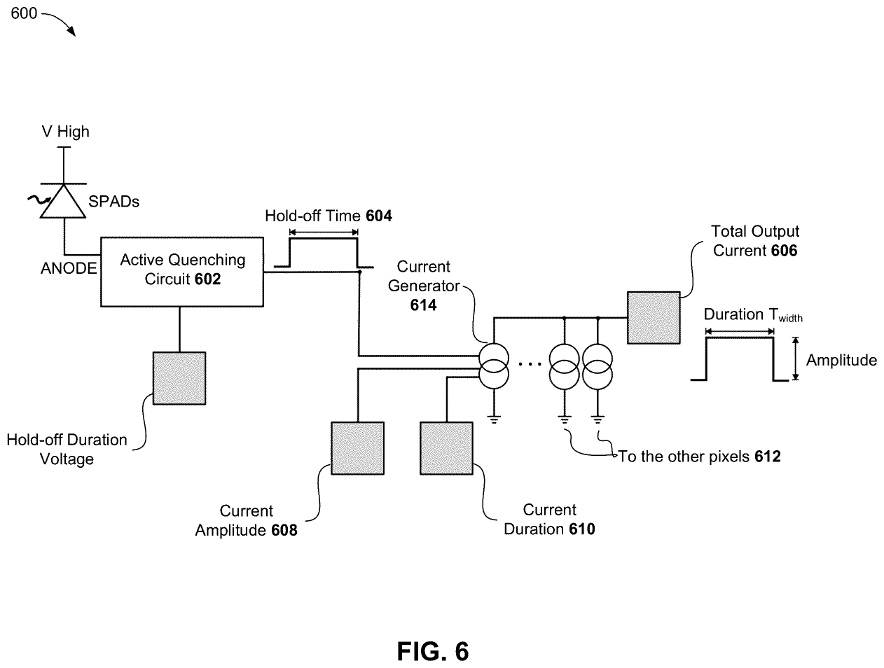

In some embodiments the peak detector includes at least one of a peak stretcher and an increment detector. In embodiments of the disclosure, an aim is to reveal the laser signal pulse in one single shot, without requiring multiple laser shots and TOF histograms. A multitude of SPADs are driven by their own active quenching circuits (AQC). When triggered, the corresponding AQC turns on a current generator that provides a programmable current pulse, with fixed width T_{width} and amplitude (see FIG. 6). The SPAD contributions are summed together to obtain an overall signal containing the concurrent photon events that happened within the last T_{width} time duration. This summing can be performed through a summing node, for example a trans-impedance amplifier (TIA). In this way, given that a SPAD is sensitive to one photon and cannot signal if more than one photon was detected, the overall sum can be considered to be a “photon number resolved” up to a total number of concurrent photons equal to the total number of SPADs.

A peak detector circuit (also known as peak follower or peak stretcher) holds the highest signal peak since the emitted laser shot pulse. A further component, the increment detector, signals whether a new peak higher than a previous peak stored by the peak detector is detected and outputs a pulse each time a higher peak is sensed. This pulse triggers the time measuring device (e.g., the on-chip time-to-digital converter (TDC)), which stores the time-of-flight (TOF) of the peak, replacing the one previously stored.

In such embodiments the highest signal is detected after one single laser shot and further provides the corresponding TOF through a digital output bus. It provides background filtering with no need to perform multiple laser shots, neither multiple TOF acquisitions, nor histogram building and post-processing, which is typically required for the time-correlated single-photon counting (TCSPC) technique). In addition, the sensor associated with embodiments of the instant disclosure requires neither programming nor post-processing.

In some embodiments the increment detector is implemented as at least one of an AC coupling and a comparator. As an AC coupling (or a “derivator”), the derivative signal of the output of the peak detector provides a pulse every time the output of the peak detector increases (e.g., each time a new peak is detected). As a comparator, the increment detector senses each time the output of the peak detector differs (e.g. is higher) than the input to the comparator, in order to signal that a new peak has been acquired. The increment detector is implemented in a simple and effective way, with no need of sampling the whole analog waveform and converting this sampled waveform through a high-rate analog to digital converter (ADC). Similarly, another solution may be to observe the derivative and compute the TOF if the derivative performs a pulse and returns to zero. Returning to zero signals the correspondence of the precise peak. This may also be used as an extension of methods disclosed herein.

In some embodiments, the photon detector is configured to output a signal upon impinging on the detector by multiple photons. For example the detector may be configured to output upon impinging thereon by a particular minimum number of photons, and this minimum number may be adjustable in some embodiments. In some embodiments, the detector is an avalanche photo diode (APD), providing an analog signal proportional to the number of detected photons, or an analog silicon photomultiplier (SiPM) providing an analog signal proportional to the number of triggered microcells, or a digital SiPM providing pulses every time each microcell gets triggered. For example, the impact of background noise and stray light is decreased by triggering the time measurement block (e.g., the TDC) when the increment detector detects an increment of the peak detector output corresponding to a desired minimum number, for example P, photons. For example, if P is set to 5 photons, no signal is output due to random fluctuations of the background ambient light, for example, wherein these fluctuations can be up to 5 photons. In this manner, by setting P >5 there is an avoidance of acquiring TOFs associated with these undesired fluctuations or unwelcome events. A selectable multi-level detector can sense the output of the AC coupling, providing a valid flag or signal only if the AC signal (i.e., the intensity of the peak increment) overcomes a defined equivalent level of at least P photons. If P is set sufficiently high (higher than the background light fluctuations), such a method may allow to flag pulses which are higher than the background, while also being unresponsive to the background fluctuations.

As an example, by using a detector that outputs a signal upon detection of a single photon, if no object is present in the field of view of the system, the system would only be measuring the TOF of any new peaks due to random fluctuations of the background light. By implementing the use of a detector which outputs a signal upon detection of P photons, the impact of random fluctuations is reduced, and only the TOF of the useful laser return is measured and stored if such a peak is higher than the highest background peak by at least P photons. In this way, it is possible to determine if an object is likely not present in the field of view of the system.

In some embodiments the photon detector may be one of a multitude of single-photon detectors such as a single-photon avalanche diode (SPAD), a silicon photomultiplier (SiPM), and an avalanche photodiode (APD). In some embodiments, a multitude of pixels include a SPAD, an active quenching circuit (AQC) and a quantized current generator.

In some embodiments, each pixel may include a SPAD with a quenching resistor in series and all SPADs can be put in parallel similar to the function of an analog silicon photomultiplier (SiPM). In this way, the analog avalanche current of each pixel is summed to the currents of all other pixels. The total SiPM output signal (either current or voltage) is proportional to the number of pixels triggered by photons and this signal feeds the peak detector and the following functional blocks of the system as described elsewhere herein.

An advantage of using an analog SiPM-like detector (wherein each pixel includes a SPAD and a resistor) is that this configuration provides a higher fill-factor compared to a digital SPAD array (wherein each pixel includes a SPAD and an AQC). It is noted that a potential disadvantage of using an analog SiPM-like detector defined above, is that the current pulse which may be associated with each pixel is set or defined by the detector response and detector parasitics and thus is not user-adjustable.

In some embodiments the method further includes sensing, by an amplitude sensor, an amplitude of the analog signal pulse at one of a trans-impedance amplifier (TIA) and the analog peak detector. In such embodiments there may be an additional functional block that senses the amplitude at the output of the TIA or at the output of the peak detector, in order to provide an output digital code proportional to the “Intensity” of the signal from the detector (e.g. herein this signal is proportional to the number of coincident detected photons within the peak). Such an additional functional block may be referred to herein as a peak intensity digitizer. In some embodiments the amplitude sensor is at least one of an analog-to-digital convertor (ADC) and a comparator (or a set of comparators). For example, a B-bit ADC may provide information if the peak was composed by 1, 2, 3, . . . 2^{B} photons. Similarly, four comparators could classify the peak among four different rankings (e.g., between 1-9 photons, or 10-20 photons, or 21-35 photons, or 36-50 photons). In some embodiments the amplitude of the analog signal pulse is proportional to a number of photons detected within a duration of time.

In some embodiments, information relating to the height of the peaks can be determined or detected wherein this information can be indicative of the intensity of the signal. This information relating to the height of the peaks or intensity of the signal can allow for the classification into a histogram of the measured TOF based on the “strength” of the detected signal, which in turn can provide a means for further processing of the signal by weighting the TOF data with the Intensity data.

In some embodiments the method is implemented by a device configured as an element, wherein a plurality of these elements is configured into an array. As an example, there can be an array of N by M elements, where each element of the array is an independent sensor or device. In this manner, the array of elements can provide an image associated with N×M TOFs associated with N×M spatial spots associated with one or more objects in a scene under observation. Such an image could be the desired full field-of-view of the scene (and as such with no further scanning required), or a sub area of the scene. In the latter case, a scanning mechanism can be configured to progressively move this N×M sub area across the different sub-field-of-views of the scene, in order to acquire a wider or complete representation of the field-of-view. In some embodiments, each of the elements of the array can work independently and collect light from one spot associated with the scene.

In some embodiments one or more optical components may be required, such that the device implementing the method of the instant disclosure may be similar to a normal camera. As an example, each spot of the scene can be imaged onto a pixel using a lens and optics. Further improvements could be used to allow for diffractive optic elements (DOE), which may focus laser light to specific spots of the scene under observation and then collect the returning light from those spots, focusing the returning light onto the corresponding pixel, which may further reduce undesired optical crosstalk or interference or signal noise.

Such embodiments allow the acquisition of multiple-spots of a scene in just a single-shot of the laser pulse. The image may cover the full scene (no need of scanning) or a part of the scene. In this way an image can be acquired from a single shot or multiple-shots and multiple scans can be employed to acquire a wider scene. The configuration of a wider scene may be considered to be a plurality of field-of-views and increase in the number of image pixels.

In some embodiments repeating the method provides a further TOF ranging. This aspect may be used to view a different object reflection by exploiting a gate signal (a signal that can filter out the events in a defined interval). In a first laser pulse, once an object is detected it may be filtered out in a second laser pulse (shining the same spot), so that this first object is not detected and a second object can be revealed behind the first object. The gate signal can be used to filter out also first reflection due to optical parts. This embodiment provides the ability to detect more objects in the same line of sight, at the cost of one more laser pulse. This feature may not be required if the first object is transparent, as the same photons coming from the single laser shots are reflected by the first object (but are not detected because the gate signal is OFF) and then also by the second, farther away object (and are detected because the gate signal is ON).

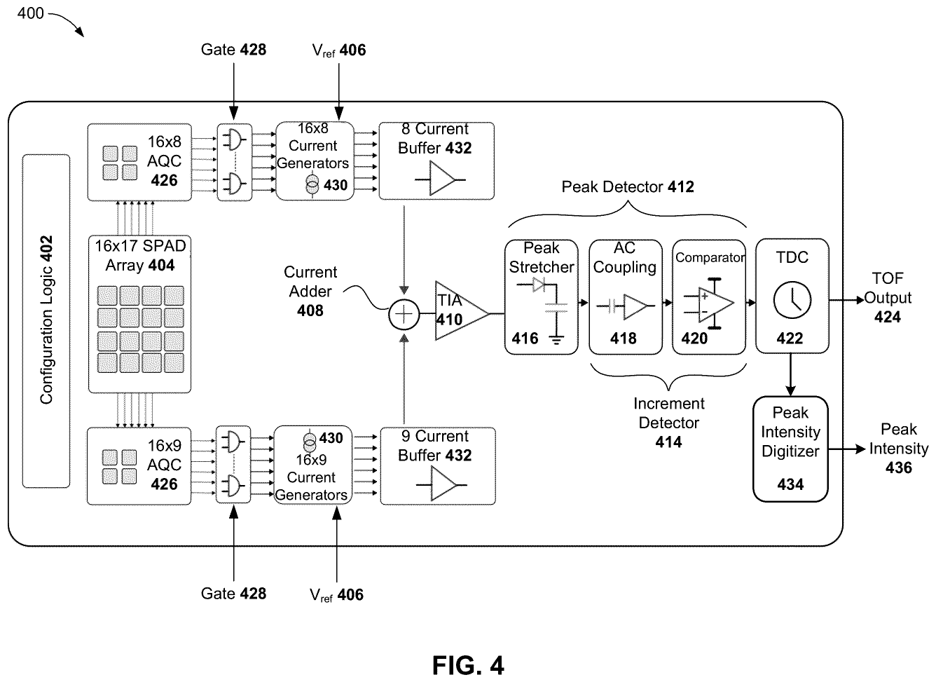

FIG. 4 illustrates an example analog architecture 400 of a device in accordance with embodiments of the present disclosure.

Referring now to FIG. 4, in addition to the on-chip electronics (configuration logic 402) the SPAD array 404 (e.g., 16×17=272 pixels) is depicted, so as to reach single-photon sensitivity within each SPAD, while providing also multi-photon capability across the array (a dynamic range of maximum 272 coincident photons), avoiding saturation and pile-up distortion (due to the limit of 1 photon per SPAD a time). Configuration logic 402 may be used for programming each block of the sensor, for example which SPAD to enable and which to permanently disable (if it is, for example defective). Configuration logic 402 may also be used in relation to the resolution of the TDC, or the threshold T of the comparator 420. Each SPAD pixel generates a quantized current output, which can be transferred to one or more active quenching circuits (AQC) 426 coupled to the SPAD array 404. Those skilled in the art will understand that an AQC and a variable load quenching circuit (VLQC) may also be used interchangeably. AAQC is a quenching circuit that is configured to have a high compactness, cross-talk avoidance and low after pulsing. In an AQC a single transistor performs the sensing, quenching and reset tasks which can reduce the overall detector parasitic capacitance and system power consumption, pixel to pixel optical cross-talk and after pulsing. The signal from the AQC is gated by gate 428 for transmission to a current generator 430 wherein the amplitude and width of the signal can be user programmed (e.g., through external V_{ref} voltage references 406 or through the configuration logic 402). SPAD signal duration may be adjustable (either digital or analog voltage or current) to match the laser width and increase the signal-to-noise ration of the acquisition. The signal can be subsequently transferred to a current buffer 432 which is connected to a current adder 408.

The global current adder 408 and a trans-impedance amplifier (TIA) 410 sum all currents and provide an overall analog voltage signal, whose amplitude is proportional to the number of concurrent photons, detected at the same time (within the width duration of each current pulse).

An analog peak detector 412 tracks the intensity of such a voltage signal, by increasing its output when the input intensity increases but staying constant when the input decreases. In some embodiments the analog peak detector 412 includes at least one of a peak stretcher 416 and an increment detector 414. The increment detector 414 provides a digital pulse every time the peak detector's 412 output increments (i.e., a new signal peak is detected, higher than any previous one since the last laser shot). In some embodiments the increment detector is implemented as at least one of an AC coupling 418 and a comparator 420. The comparator 420 may be multi-threshold (programmable) at AC coupling 418 output, providing more immunity to noise and information of object presence. If no objects are present very few noise events perform peaks much higher than other noise peaks.

A time-to-digital converter (TDC) 422 measures the time-of-flight (TOF) of the last peak (as soon as the increment detector 414 provides a pulse) and stores the value into one single memory cell, overwriting the previous content (belonging to a previous peak with lower intensity than the present one). TDC may possess sophisticated architectures and circuitry (for example when trying to reach picosecond resolutions, high accuracies and very narrow precisions). In some embodiments, the TDC may be tailored to the desired precision or accuracy. As an example, the TDC could consist of a fast digital counter, running at a high frequency clock, so to measure the time between a “Start” and a “Stop” pulse. As another example, a time measuring device (such as a, TDC) may be based on a time-to-amplitude converter (TAC), followed by an ADC. Thus, analog time measuring systems employing a TAC and an ADC may be employed, as opposed to only digital TDC. However, the digital TDC may be easier to stop multiple times (and thereby to store only the TOF of the last highest peak), while a TAC and ADC system could be slightly more complicated to control in the same manner. A peak intensity digitizer 434 may be connected to the TDC 422 in order to digitize and provide a peak intensity 436.

Eventually, a memory cell provides the single TOF digital output 424 of the sensor, namely the TDC conversion of the TOF arrival time of the highest signal peak detected after the single-shot emitted by the pulsed laser. In some embodiments if it is detected as soon as possible when the derivative signal becomes positive (i.e. the peak stretcher increases), the detection is the rising edge of the new peak (not the center of the peak). Therefore the TOF would be anticipated (compared to the correct position of the TOF centroid). In other embodiments it may be more precise to monitor when the derivative signal rises and then decreases to go back to zero. In this way, when the derivative is zero the TOF would actually correspond to the peak of the signal (i.e., the right centroid of the incoming photons).

An example implementation of the chain of events that tracks the incoming photon rate is given by a variable load quenching circuit (VLQC) 426 which provides the digital output and can be filtered out by a gate 428. The current generator 430 (or another digital to analog conversion) may be used to sum the photons, while the current buffer 432 gathers all of these signals.

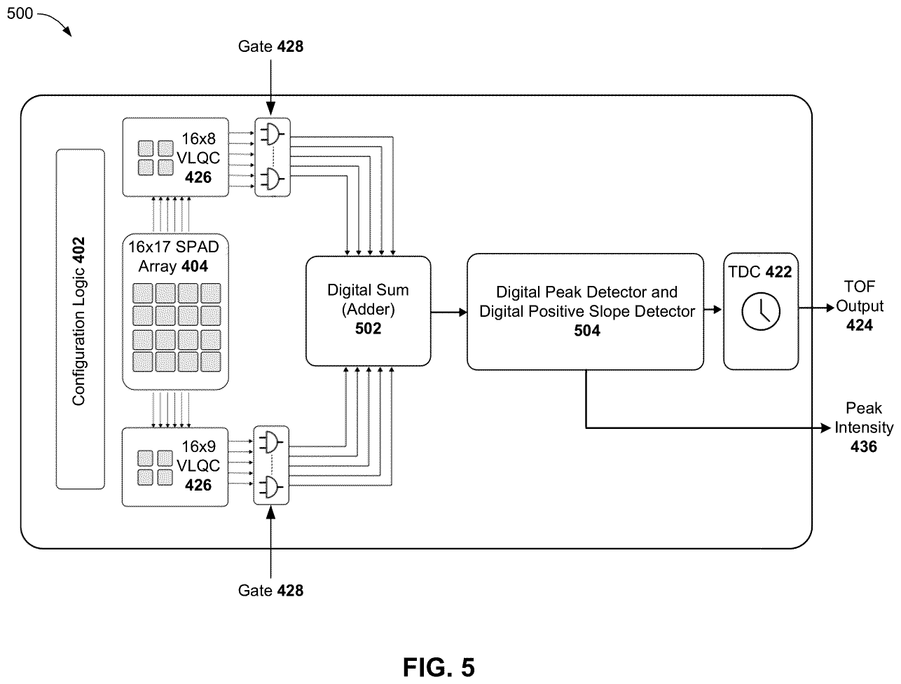

FIG. 5 depicts a digital architecture 500 of a device in accordance with embodiments of the present disclosure. The primary difference between the analog system illustrated in FIG. 4 and the embodiment illustrated in FIG. 5, is the inclusion of a digital sum adder 502, and a digital peak detector and digital positive slope detector 504, which replace multiple analog components previously described with respect to FIG. 4.

Referring now to FIG. 5, in addition to the on-chip electronics (configuration logic 402) the SPAD array 404 (e.g., 16×17=272 pixels) is depicted, so as to reach single-photon sensitivity within each SPAD, while providing also multi-photon capability across the array (a dynamic range of maximum 272 coincident photons), avoiding saturation and pile-up distortion (due to the limit of 1 photon per SPAD a time). The SPAD generates an avalanche current, which is converted into a digital pulse by the variable load quenching circuit (VLQC) 426, and added to all the other VLQC digital pulses. A VLQC is a quenching circuit that is configured to have a high compactness, cross-talk avoidance and low after pulsing. In a VLQC a single transistor performs the sensing, quenching and reset tasks which can reduce the overall detector parasitic capacitance and system power consumption, pixel to pixel optical coupling and after pulsing. The signal from the VLQC is gated by gate 428 for transmission to a digital sum adder 502 and subsequently transmitted to a digital peak detector and digital positive slope detector 504. The digital sum adder 502 is a digital block that adds all of the pulses digitally (i.e., it is a cascade of full adder architectures). The digital peak detector may be a logic component that compares the value from the adder to the one stored in a memory (with a binary equality comparator (e.g., EXNOR based) and replaces the value into a memory each time a peak equal to (or greater than) a previous one is detected. The slope detector may bean optional component; as soon as the digital peak detection block finds a new value equal to or higher than the previous one, this instance can be used as the new TOF without any additional block. The digital peak detector may provide a measurement for the peak intensity 436.

A time-to-digital converter (TDC) 422 measures the time-of-flight (TOF) of the last peak (as soon as the digital peak detector and digital positive slope detector 504 provides a pulse) and stores the value into one single memory cell, overwriting the previous content (belonging to a previous peak with lower intensity than the present one). TDC may possess sophisticated architectures and circuitry (for example when trying to reach picosecond resolutions, high accuracies and very narrow precisions). In some embodiments, the TDC may be tailored to the desired precision or accuracy. As an example, the TDC could consist of a fast digital counter, running at a high frequency clock, so to measure the time between a “Start” and a “Stop” pulse.

Eventually, a memory cell provides the single TOF digital output 424 of the sensor, namely the TDC conversion of the arrival time of the highest signal peak detected after the single-shot of the pulsed laser. In some embodiments if it is detected as soon as possible when the digital sum 502 increases, the detection is the rising edge of the new peak (not the center of the peak). Therefore the TOF would be anticipated (compared to the correct position of the TOF centroid). In other embodiments it may be more precise to monitor when the digital sum 502 rises and then settles to a constant value. In this way, when it does not increment (i.e., the derivative is zero) the TOF would actually correspond to the peak of the signal (i.e., the right centroid of the incoming photons).

FIG. 6 is a block diagram of a SPAD pixel 600 which generates a quantized current pulse (with fixed time duration and amplitude) every time a photon is detected. Following this, the currents from all SPAD pixels are summed together, so to provide the total output current analog signal, feeding a peak detector. Each SPAD pixel 600 may consist of an active quenching circuit (AQC) 602, to sense the avalanche ignition within the SPAD due to a photo detection, to quench the avalanche process, to reset the SPAD back to operation after a hold-off time 604, and to provide a digital pulse) and a current generator 614. The current generator 614 of each SPAD pixel generates a quantized current output, with fixed amplitude (e.g., set by means of a control pin 608 or through the configuration logic 402) and fixed width T_{width} duration (e.g., set by means of a control pin 610 or through the configuration logic 402). All current generators 614 are connected together (shown as 612) so to form a total output current analog signal 606. All parameters of the pixels may be programmable, for example, through analog or digital pins or through the Configuration Logic 402, to provide flexibility.

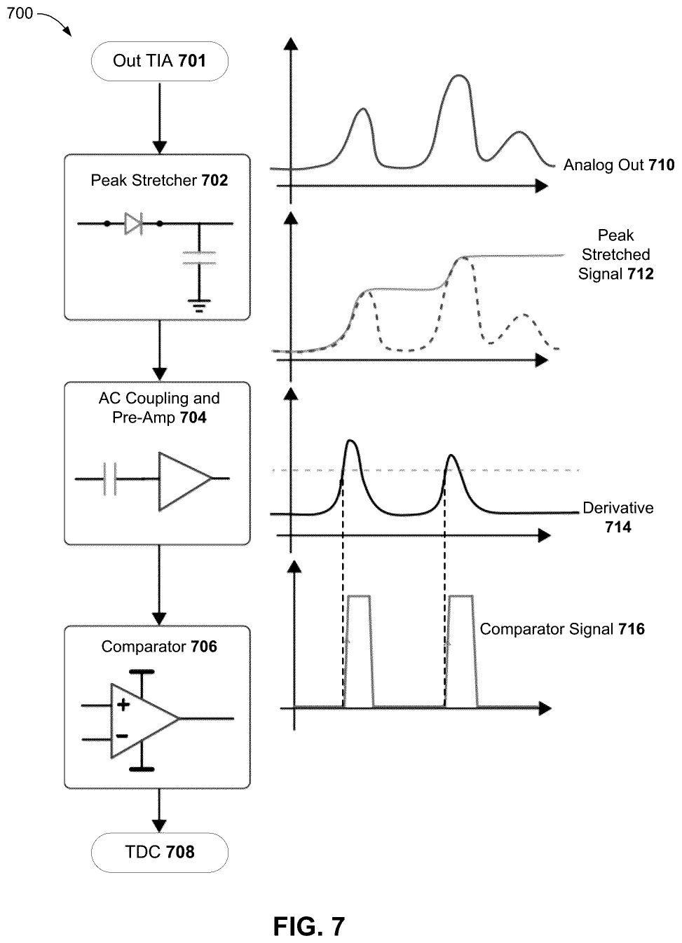

FIG. 7 depicts an example working principle of a peak detector 700. The peak detector senses the detected analog signal output 710 from the SPAD array (TIA 701) and triggers the TDC every time a new peak, higher than the previous one, is detected, for example by means of an AC coupling 704 and a comparator 706.

The total output current analog signal 710 (as is or converted into a voltage signal) feeds the peak stretcher 702, whose task is to stretch the highest analog signal so far (shown as peak stretcher signal 712), and the following increment detector, which provides a pulse every time the peak detector 700 detects a new peak, higher than the previous one since the last laser shot. Every time this happens, the peak detector 412 (through the increment detector 414) triggers the TDC 708, which measures the corresponding TOF. Since only the TOF of the highest peak is needed, the TDC 708 keeps overwriting the single memory cell with the new TOF.

The increment (intensity) detector may comprise the AC high-pass coupling 704, giving a pulse every time the peak detector 700 detects a new peak, followed by the comparator 706 with constant threshold (independent of the background level and any other scene parameter). The intensity detector may also comprise a comparator 706 comparing the input and output of the peak stretcher 702, so to identify when the peak detector 702 holds a new peak 712 while the input 710 decreases.

The derivative 714 is applied to the peak stretched signal 712. Every time the peak stretcher 702 detects new peaks, it shows a rising edge and the derivative (AC coupling 704) block provides a pulse. When the peak stretched signal 712 is constant, the derivative signal 714 is almost zero (or with a minor offset).

It will be appreciated that, although specific embodiments of the technology have been described herein for purposes of illustration, various modifications may be made without departing from the scope of the technology. The specification and drawings are, accordingly, to be regarded simply as an illustration of the disclosure as defined by the appended claims, and are contemplated to cover any and all modifications, variations, combinations or equivalents that fall within the scope of the present disclosure.

Although the present invention has been described with reference to specific features and embodiments thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A method for time-of-flight (TOF) ranging, the method comprising:
generating, by each photon detector pixel in a photon detector array, a quantized current pulse each time a predefined number of photons are detected by the respective photon detector pixel;
summing, by a current adder, the quantized current pulses from all photon detector pixels to create an analog signal pulse;
outputting, by a peak detector, a digital pulse for each instance where an intensity of the analog signal pulse is greater than signal peaks previously measured;
measuring and recording, by a time-to-digital converter (TDC), a TOF each time the digital pulse is provided; and
outputting, by a TOF output, a single TDC result indicative of a TOF associated with the analog signal pulse having a highest intensity.

2. The method of claim 1, wherein the peak detector includes at least one of:
a peak stretcher; and
an increment detector.

3. The method of claim 2, wherein the increment detector includes at least one of:
an AC coupling; and
a comparator.

4. The method of claim 1, wherein the predefined number of photons is one.

5. The method of claim 1, wherein the photon detector array includes at least one of:
a single-photon avalanche diode (SPAD);
a silicon photomultiplier (SiPM); and
an avalanche photodiode (APD).

6. The method of claim 1 further including sensing, by an amplitude sensor, an amplitude of the analog signal pulse at one of:
a trans-impedance amplifier (TIA); and
the peak detector.

7. The method of claim 6, wherein the amplitude of the analog signal pulse is proportional to a number of photons detected within a duration of time.

8. The method of claim 1, wherein the amplitude sensor comprises at least one of:
an analog-to-digital convertor (ADC); and
a comparator.

9. The method of claim 1, wherein a further TOF ranging is determined by repeating the steps of generating a quantized current pulse, summing the quantized current pulses, providing a digital pulse, measuring and recording the TOF and providing the single TDC result.

10. The method of claim 1, wherein the peak detector is configured as a digital peak detector.

11. A device for time-of-flight (TOF) ranging, the device comprising:
a photon detector array including a plurality of photon detectors, each photon detector configured to generate a quantized current pulse each time a predefined number of photons is detected;
a current adder configured to sum the quantized current pulses from all photon detectors to create an analog signal pulse;
a peak detector configured to output a digital pulse for each instance where an intensity of the analog signal pulse is greater than signal peaks already measured;
a time-to-digital converter (TDC) configured to measure and record a time-of-flight (TOF) each time the digital pulse is provided; and
a TOF output configured to output a single TDC result indicative of the TOF associated with the analog signal pulse having a highest intensity.

12. The device of claim 11, wherein the peak detector includes at least one of:
a peak stretcher; and
an increment detector.

13. The device of claim 12, wherein the increment detector includes at least one of:
an AC coupling; and
a comparator.

14. The device of claim 11, wherein the predefined number of photons is one.

15. The device of claim 11, wherein the photon detector array includes at least one of:
a single-photon avalanche diode (SPAD);
a silicon photomultiplier (SiPM); and
an avalanche photodiode (APD).

16. The device of claim 11 further including an amplitude sensor configured to sense an amplitude of the analog signal at one of a trans-impedance amplifier (TIA) and the analog peak detector.

17. The device of claim 16, wherein the amplitude of the analog signal pulse is proportional to a number of photons detected within a duration of time.

18. The device of claim 11, wherein the amplitude sensor comprises at least one of an analog-to-digital convertor (ADC) and a comparator.

19. The device of claim 11, wherein the peak detector is configured as a digital peak detector.
